(19) United States
(12) Patent Application Publication
(10) Pub. No.: US 2002/0132428 A1
(43) Pub. Date: Sep. 19, 2002

(54) Method for fabricating a MOS transistor of an embedded memory

(76) Inventors: Sun-Chieh Chien, Hsin-Chu City (TW); Chien-Li Kuo, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/795,327

(22) Filed: Mar. 1, 2001

(51) Int. Cl. H01L 21/336

(52) U.S. Cl. 438/258

(57) ABSTRACT

The present invention provides a method for manufacturing a MOS transistor of an embedded memory on the surface of a semiconductor wafer. The method of the present invention involves the deposition of a first dielectric layer and an undoped polysilicon layer, respectively, in the periphery circuit region of the silicon substrate of the semiconductor wafer. Thereafter, a plurality of gates and lightly doped drains of the MOS transistors are formed in the memory array area of the semiconductor wafer, with each gate comprising a second dielectric layer, a doped polysilicon layer, a silicide layer and a protection layer, respectively. Next, both the undoped polysilicon layer and the first dielectric layer in the periphery circuit region are etched to form gates of each MOS transistor in the periphery circuit region. Finally, lightly doped drains, spacers, sources and drains of each MOS transistor in the periphery circuit region are formed. The implantation processes that form the sources and drains also simultaneously implant the undoped polysilicon layers of each gate.

### BACKGROUND OF THE INVENTION

1. Field of the Invention

The present invention relates to a method of fabricating a MOS transistor of an embedded memory.

2. Description of the Prior Art

With the increasing integration and consideration of performance and cost, the semiconductor industry has been motivated to integrate both memory cell arrays and high-speed logic circuit elements onto a single chip, to form a so-called embedded memory. The effect is a reduction in the surfaces of chips as well as an increase in the speed of signal processing.

To optimize the speed of an embedded memory, a process is required to create both dual gate oxide layers and gate polysilicon layers of different thickness. The MOS transistor formed above the periphery circuit region comprises a thin gate oxide layer to increase access speed, and a thick gate polysilicon layer to prevent boron penetration of the PMOS transistor.

Please refer to FIG. 1 to FIG. 8. FIG. 1 to FIG. 8 are cross-sectional diagrams of a prior art method for manufacturing a metal-oxide-semiconductor (MOS) transistor of an embedded memory on a semiconductor wafer 10. As shown in FIG. 1, the surface of the silicon substrate 12 is divided into a memory array area 13 and a periphery circuit region 15. The memory array area 13 contains a cell well 14, and the periphery circuit region 15 contains at least one N-well 16 and at least one P-well 18. Each region is separated by several shallow trench isolation structures 11.

The prior art method first involves forming a gate oxide layer 20 on the semiconductor wafer 10. Next, as shown in FIG. 2, a photoresist layer 22 is formed above the memory array area 13 and is used as a mask for etching the gate oxide layer 20 in the periphery circuit region 15. After completely removing the photoresist layer 22, a thermal oxidation process is performed to form another oxide layer 24 of a different thickness on the surface of the semiconductor wafer 10, as shown in FIG. 3.

Then, as shown in FIG. 4, a polysilicon layer 26, a polycide layer 28 and a cap layer 30 composed of silicon nitride are sequentially formed on the semiconductor wafer 10. As shown in FIG. 5, a photoresist layer 32 is formed above the cap layer 30 and a lithographic process is performed to define gate patterns of both the memory array area 13 and the periphery circuit region 15 in the photoresist layer 32. Thereafter, as shown in FIG. 6, the patterned photoresist layer 32 is used as a mask layer to perform an etching process for removing the cap layer 30, the polycide layer 28 and the polysilicon layer 26 down to the surface of the gate oxide layer 24 so as to simultaneously form a plurality of gates 34 above the cell well 14 of the memory array area 13 and a plurality of gates 36 above both the N-well 16 and P-well 18 of the periphery circuit region 15.

Next, as shown in FIG. 6, the photoresist layer 32 above the cap layer 30 is completely removed, followed by performing an ion implantation process to form a doped region (not shown) on the surface of the silicon substrate 12 adjacent to each gate 34, 36. Thereafter, a rapid thermal process (RTP) is performed to drive dopants in the doped region into the silicon substrate 12 so as to form lightly doped drains (LDD) 38 of each MOS transistor.

As shown in FIG. 7, a silicon nitride layer (not shown) is deposited on the semiconductor wafer 10 followed by performing an anisotropic etching process to etch back portions of the silicon nitride layer and form a spacer 40 around each gate 34, 36 of the memory array area 13 and the periphery circuit region 15, respectively. Then, an ion implantation process is performed to form a source and drain of each MOS transistor in the periphery circuit region 15. A photoresist layer is first formed to cover the memory array area 13 and the gates 34, 36 of the N-well 16. Then, N-type dopants are used to implant the surface of the P-well 18 so as to form a doped region 44, followed by the removal of the photoresist layer. Next, another photoresist layer is formed to completely cover the memory array area 13 and the gate 36 of the P-well 18. Then, P-type dopants are used to implant the N-well 16 of the periphery circuit region 14 so as to form a doped region 42. Thereafter, a rapid thermal process is used to drive dopants of each doped region 42, 44 into the silicon substrate 12 so as to form the source and the drain of each MOS transistor in the periphery circuit region 15.

Finally, as shown in FIG. 8, a salicide block (SAB) layer 46 is formed on the silicon substrate 12 of the memory array area 13. Then, a self-aligned silicide process is performed in the periphery circuit region 15 to form a salicide layer 48 on the surface of each source and drain so as to finish the process of manufacturing a MOS transistor of an embedded memory according to the prior art method.

The prior art method for manufacturing the embedded memory requires at least three photolithographic and etching processes and oxidation methods to form a dual gate oxide layer of different depths. Then, each MOS transistor is formed in the memory array area 11 and the periphery circuit region 13, respectively. Therefore, the manufacturing operation of the prior art is both complex and costly. As well, the polysilicon layer of the gate structures in the memory array area, which are formed together with that of the periphery circuit region, has a greater thickness than when manufactured in an ordinary memory process. As the integration of the memory array area increases, the aspect ratio between gates greatly increases. Thus, over-hanging can easily occur between two neighboring gates in the memory array area when filling the ILD layer. Avoid bridge may then be formed, resulting in short-circuiting due to the creation of an electrical connection between two neighboring gates.

### SUMMARY OF THE INVENTION

It is the primary object of the present invention to provide a method of manufacturing a MOS transistor of an embedded memory that integrates the processes of both a dual gate oxide layer and a MOS transistor as well as increases the reliability and quality of embedded memories.

The method of the present invention is to first define a memory array area and a periphery circuit region on the surface of the silicon substrate of the semiconductor wafer. A first dielectric layer and an undoped polysilicon layer are formed, respectively, on the surface of the semiconductor wafer. Next, both the undoped polysilicon layer and the first dielectric layer on the memory array area are completely removed. A second dielectric layer, a doped polysilicon layer, a silicide layer, a protection layer and a first photoresist layer are formed, respectively, on the surface of the semiconductor wafer. Thereafter, a plurality of gate patterns are defined in the first photoresist layer above the memory array area. The patterns of the first photoresist layer are used as hard masks to etch the protection layer, the silicide layer and the doped polysilicon layer down to the surface of the second dielectric layer. Then, lightly doped drains of each MOS transistor in the memory array area are formed.

A second photoresist layer is formed on the surface of the semiconductor wafer. A plurality of gate patterns are defined in the second photoresist layer above the periphery circuit region. The patterns of the second photoresist layer are used as hard masks to etch the undoped polysilicon layer down to the surface of the first dielectric layer above the periphery circuit region so as to form gates for each MOS transistor in the periphery circuit region. Thereafter, lightly doped drains of each MOS transistor in the periphery circuit region are formed. The second photoresist layer is then removed and a silicon nitride layer is formed on the surface of the semiconductor wafer to cover each gate. Then, portions of the silicon nitride layer is removed in the periphery circuit region so as to form a spacer adjacent to each gate in the periphery circuit region. Next, an ion implantation process is performed to form a source and a drain of each MOS transistor in the periphery circuit region. Finally, the undoped polysilicon layers of each gate of the MOS transistors in the periphery circuit region are simultaneously implanted.

In the present invention method of fabricating a MOS transistor of an embedded memory, gate oxide layers and gate polysilicon layers are formed of different depths on the semiconductor wafer. The result is an increase in the computing speed of MOS transistors in the periphery circuit region. Additionally, the gate depth in the memory array area is reduced so as to decrease the aspect ratio between gates and prevent the formation of void bridges between two gates when filling the ILD layer in the memory array area.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 8 are cross-sectional diagrams of manufacturing a dual gate oxide region of an embedded memory by the prior art method.

FIG. 9 to FIG. 16 are cross-sectional diagrams of manufacturing a MOS transistor of an embedded memory by the present invention.

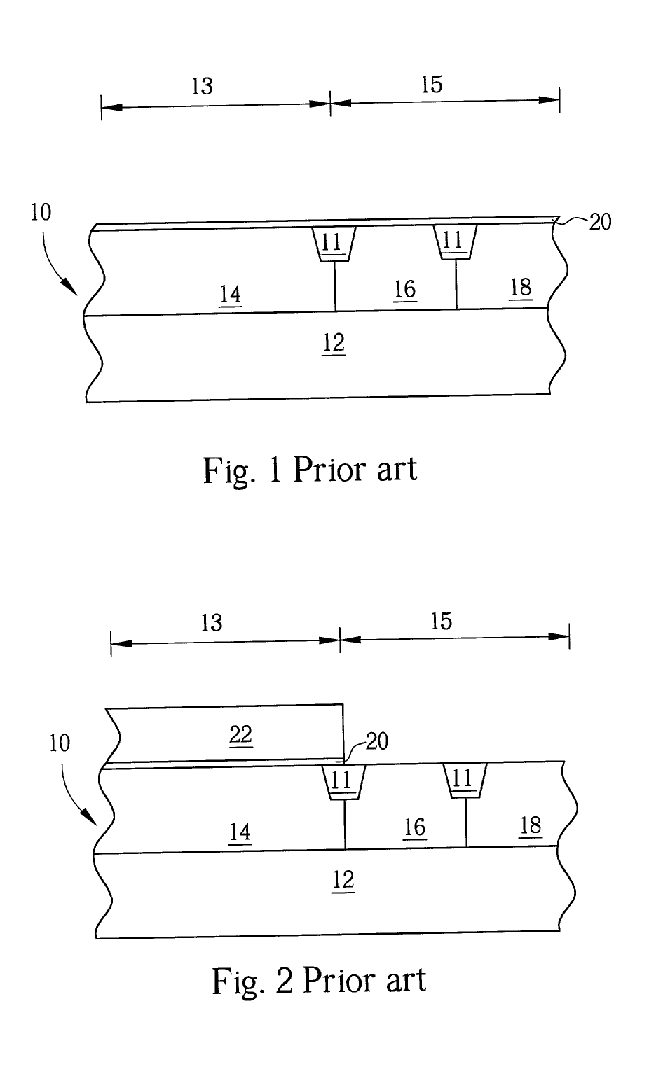

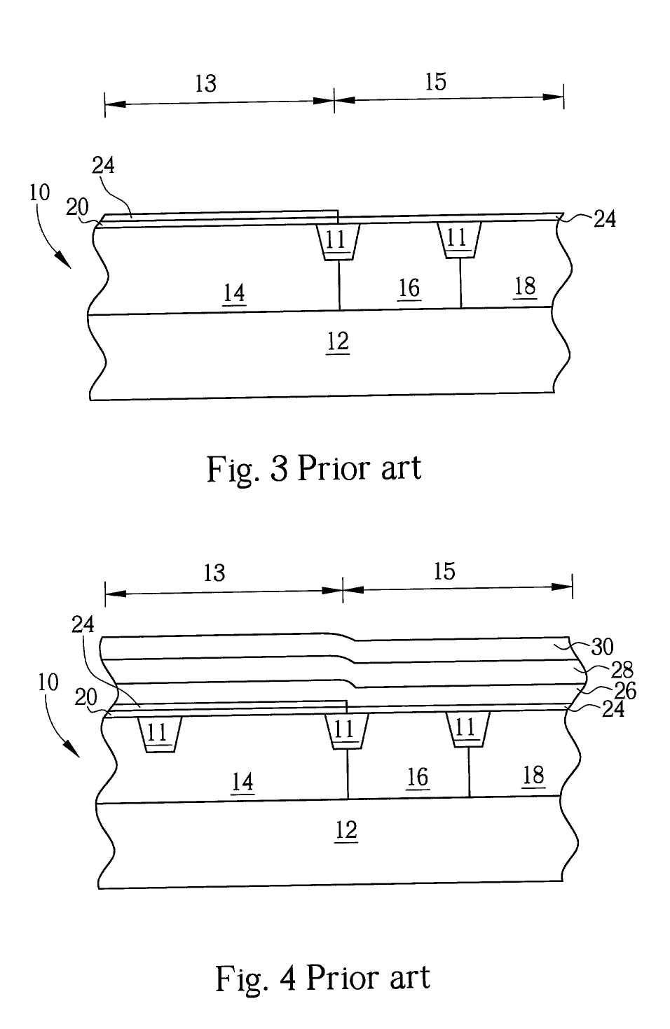

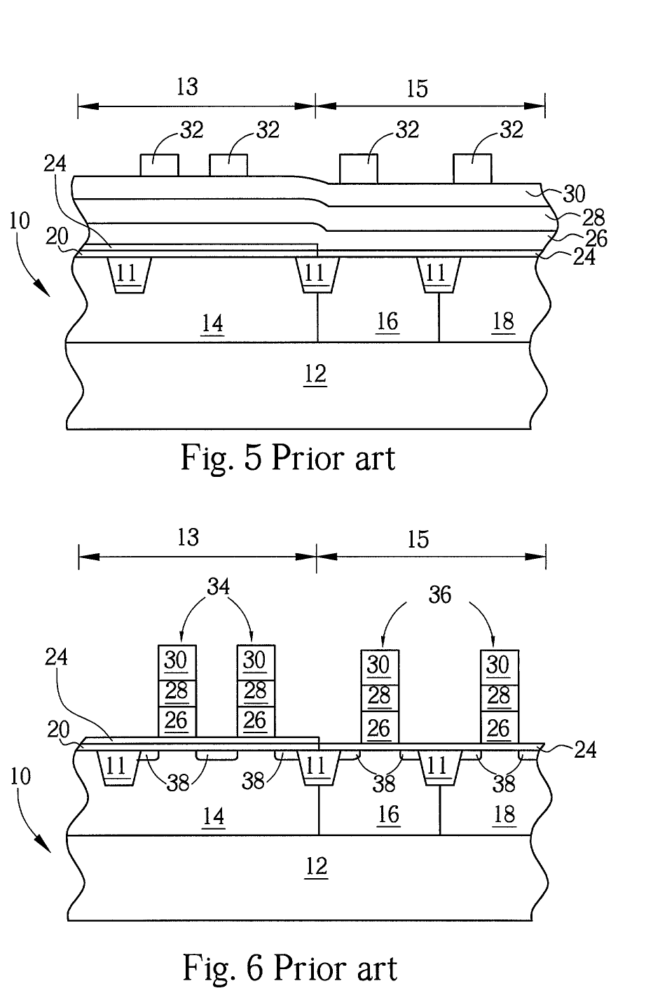

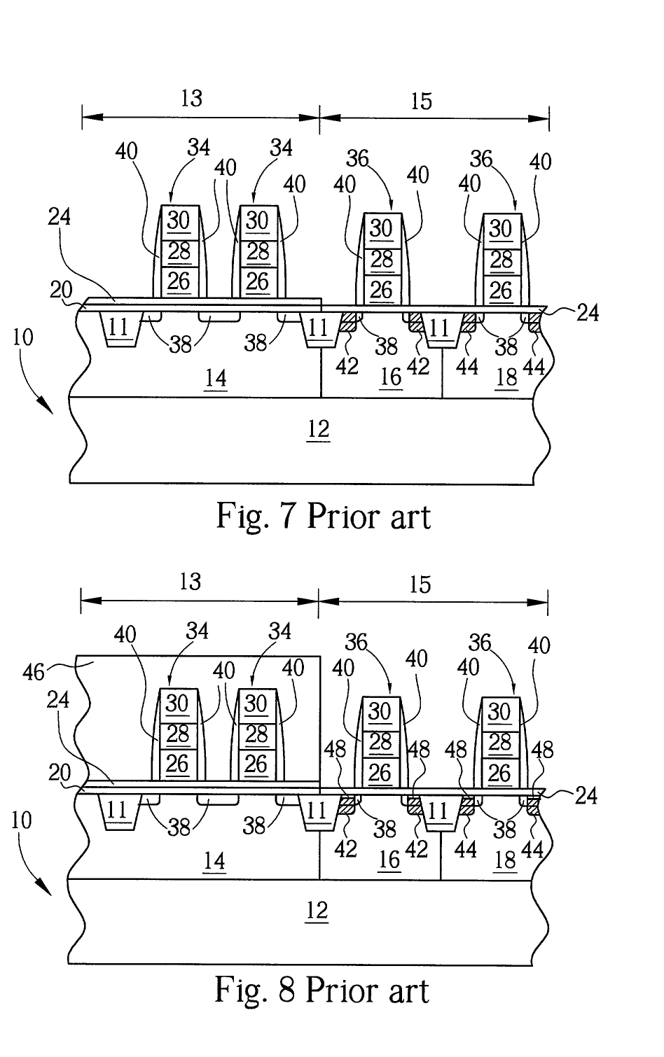

### DETAILED DESCRIPTION OF THE PREFERRED EMBODIMENT

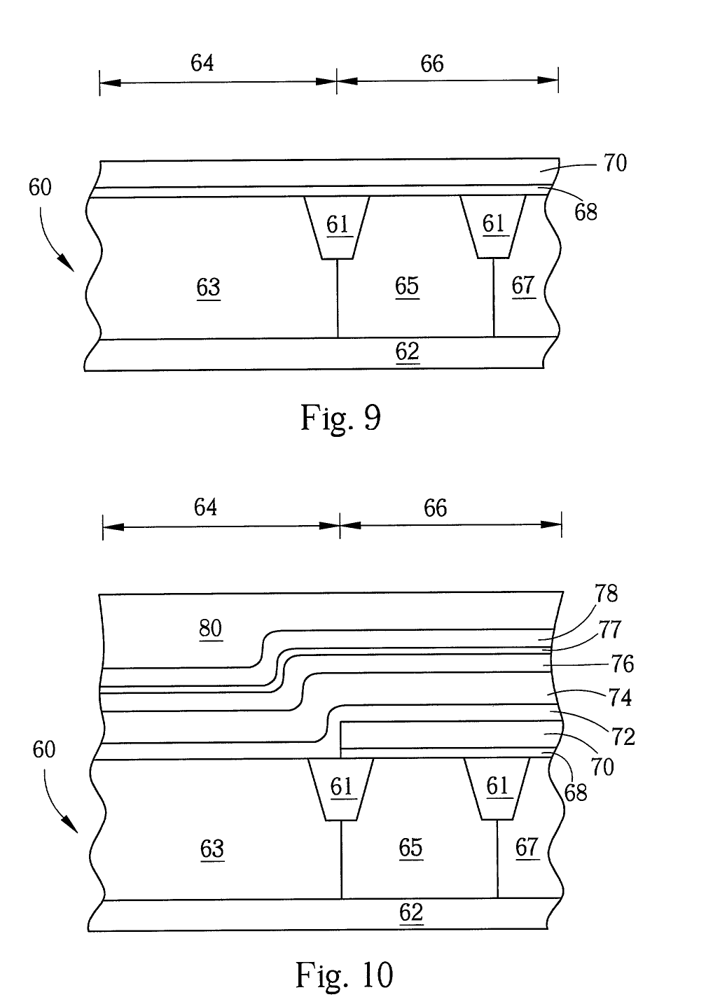

Please refer to FIG. 9 to FIG. 16 of the cross-sectional diagrams of manufacturing a MOS transistor of an embedded memory on a semiconductor wafer 30 by the present invention. As shown in FIG. 9, the semiconductor wafer 30, which includes a silicon substrate 32, is defined by both a memory array area 34 and a periphery circuit region 36 on the surface of the silicon substrate 32. The memory array area 34 comprises of at least one cell-well 33 while the periphery circuit region 36 comprises of at least one N-well 35 and at least one P-well 37. Several shallow trench isolation 31 structures are formed to separate each region.

In the present invention, a dielectric layer 38 and an undoped polysilicon layer 40 are first formed, respectively, on the surface of the semiconductor wafer 30. Then, an etching process is performed to completely remove both the undoped polysilicon layer 40 and the dielectric layer 38 above the memory array area 34. The dielectric layer 38 is composed of silicon dioxide (SiO₂) with a depth between 25˜45 angstroms (Å), and serves as the gate oxide layer for each MOS transistor in the periphery circuit region 36. The depth of the undoped polysilicon layer 40 is between 2000˜2500 angstroms (Å).

As shown in FIG. 10, a dielectric layer 42, a doped polysilicon layer 44, a silicide layer 46, a protection layer 48 and a photoresist layer 50 are formed, respectively, on the surface of the semiconductor wafer 30. The dielectric layer 42 is composed of silicon dioxide (SiO₂) with a depth between 70˜90 angstroms (Å), and serves as the gate oxide layer for each MOS transistor in the memory array area 34. The depth of the doped polysilicon layer 44 is between 600˜1000 angstroms (Å). The protection layer 48, composed of silicon nitride and also a silicon-oxy-nitride (SiOₓN_{y}) layer 47, serves as an anti-reflection coating (ARC) layer and is positioned between the protection layer 48 and the silicide layer 46.

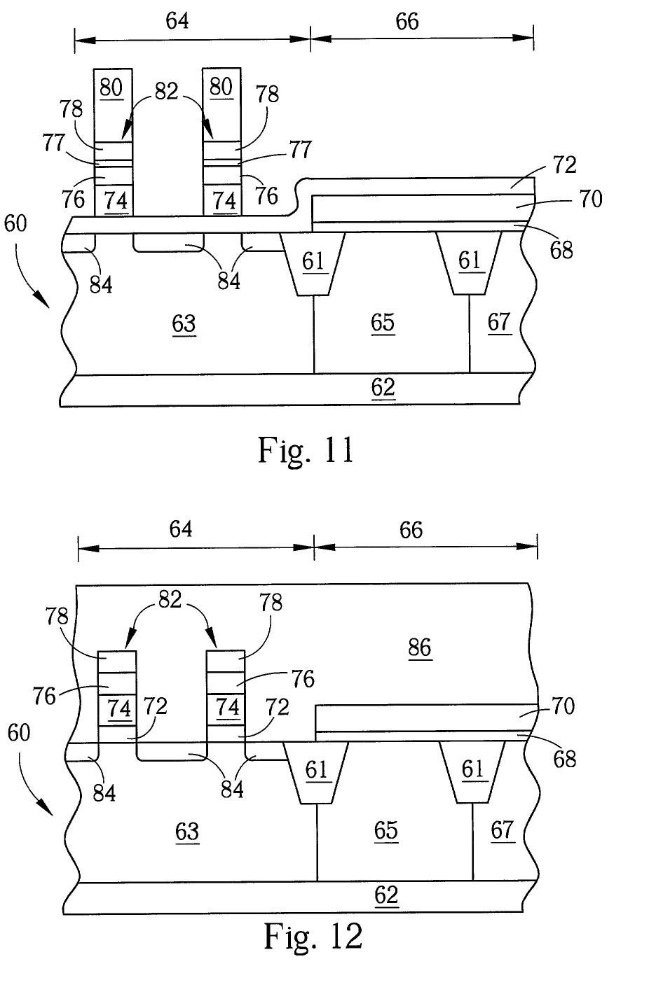

As shown in FIG. 11, a photolithographic process is performed to define a plurality of gate 52 patterns in the photoresist layer 50 in the memory array area 34. The patterns of the photoresist layer 50 are used as hard masks to etch the protection layer 48, the silicon-oxy-nitride (SiOₓN_{y}) layer 47, the silicide layer 46 and the doped polysilicon layer 44 down to the surface of the dielectric layer 42. Then, an ion implantation process is performed to form a lightly doped drain (LDD) 54 for each MOS transistor in the memory array area 34, followed by the removal of both the photoresist layer 50 and the second dielectric layer 42 in the periphery circuit region 36.

As shown in FIG. 12, a photoresist layer 56 is formed on the surface of the semiconductor wafer 30 and a photolithographic process is performed to define a plurality of gate patterns in the photoresist layer 56 in the periphery circuit region 36. A silicon-oxy-nitride (SiOₓN_{y}) layer (not shown), which serves as an anti-reflection coating (ARC) layer, is formed on the surface of the semiconductor wafer 30 before forming the photoresist layer 56.

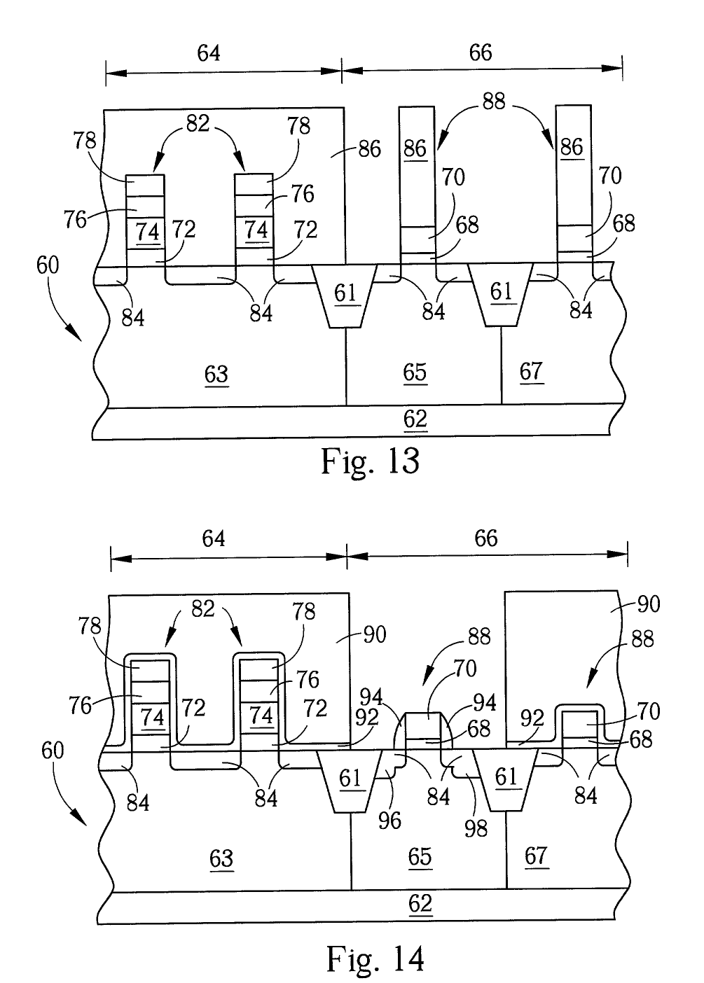

As shown in FIG. 13, the gate patterns in the photoresist layer 56 are used as hard masks to etch the undoped polysilicon layer 40 down to the surface of the dielectric layer 38 in the periphery circuit region 36 so as to form gates 58 for each MOS transistor in the periphery circuit region 36. Then, an ion implantation process is performed to form a lightly doped drain (LDD) 54 for each MOS transistor in the periphery circuit region 36.

After removal of the photoresist layer 56 and the silicon-oxy-nitride layer (not shown), respectively, two photolithographic processes are used to perform two ion implantation processes in the different implanted regions. Thus, a source 66 and a drain 68 of each PMOS and NMOS transistor are formed in the P-well 35 and N-well 37, respectively, in the periphery circuit region 36. As well, the two ion implantation processes performed in the different implanted regions also implant the undoped polysilicon layer 40 of each gate 58 on the P-well 35 and N-well 37, respectively.

As shown in FIG. 14, a silicon nitride layer 62 is formed on the surface of the semiconductor wafer 30 and the silicon nitride layer 62 covers the surface of each gate 52, 58. A photoresist layer 60 is formed in both the memory array area 34 and the N-well 37 region of the periphery circuit region 36. The photoresist layer 60 is used as a hard mask to etch portions of the silicon nitride layer 62 in the P-well region 35 of the periphery circuit region 36 to form a spacer 64 on either side of each gate 58 in the P-well region 35 of the periphery circuit region 36. Then, an ion implantation process is performed to form a source 66 and a drain 68 for each NMOS transistor in the periphery circuit region 36 as well as simultaneously implanting the undoped polysilicon layer 40 on the P-well region 35.

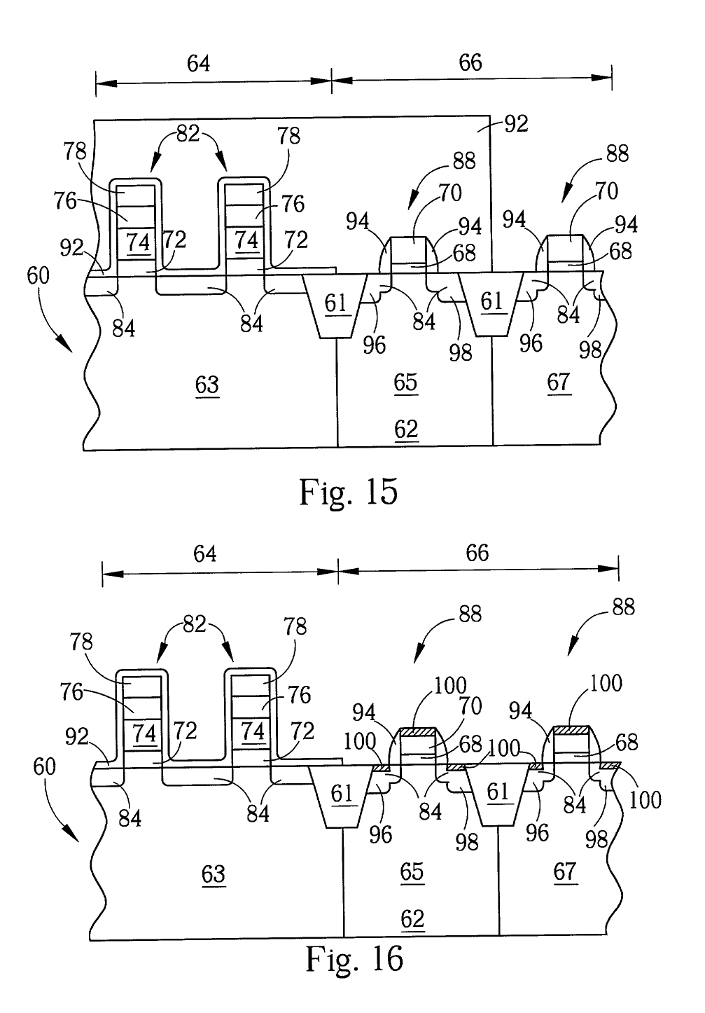

As shown in FIG. 15, the photoresist layer 60 is removed and a photoresist layer 62 is formed on the memory array area 34 and the P-well region 35 of the periphery circuit region 36. The photoresist layer 62 is used as a hard mask to etch portions of the silicon nitride layer 62 in the N-well region 37 of the periphery circuit region 36 to form a spacer 64 on either side of each gate 58 in the N-well region 37 of the periphery circuit region 36. Then, an ion implantation process is performed to form a source 66 and a drain 68 for each PMOS transistor in the periphery circuit region 36 as well as simultaneously implanting the undoped polysilicon layer 40 on the N-well region 37.

As shown in FIG. 16, after the formation of the source 66 and the drain 68 of each MOS transistor in the periphery circuit region 36, the photoresist layer 62 is removed and a metal layer (not shown) comprised of Co is formed on the surface of the semiconductor wafer 30. The metal layer covers the surfaces of the sources 66, the drains 68, and the gates 52, 58 in the periphery circuit region 36. Then, a first rapid thermal process (RTP) is performed at a temperature between 400° C. and 600° C. for a duration of 10 to 50 seconds to diffuse Co atoms of the metal layer to the surface of each source 66, drain 68 and gate 52, 58. Then, a wet etching process is performed to remove the unreacted metal layer from the surface of the semiconductor wafer 30. Finally, a second rapid thermal process (RTP) is performed at a temperature between 600° C. and 800° C. for a duration of 10 to 50 seconds to form a salicide layer 70 on the surface of each source 66, drain 68 and gates 52, 58 in the periphery circuit region 36. Ti, Ni, or Mo can replace Co as the metal in the metal layer.

The present method for manufacturing a MOS transistor of an embedded memory first forms a thin dielectric layer and a thick undoped polysilicon layer to serve as a dielectric layer and a conductive layer, respectively, for each gate in the periphery circuit region on the surface of the semiconductor wafer. Then, a thick dielectric layer, a thin doped polysilicon layer, a silicide layer and a protection layer are formed, respectively, to form the structure of each gate in the memory array area.

In contrast with the prior art method of fabricating a MOS transistor of an embedded memory, the present invention integrates the processes of the dual gate oxide region as well as forms the gate polysilicon layers of different depths. The decrease in depth of the gate oxide layer in the periphery circuit region results in an increase in the computing speed of the MOS transistor in the periphery circuit region. As well, a thin doped polysilicon layer serves as a gate conductive layer of the MOS transistor in the memory array area to reduce the depths of the gates in the memory array area. As a result, the aspect ratio between gates is significantly decreased to prevent the formation of void bridges between two gates when filling the ILD layer in the memory array area.

What is claimed is:

1. A method for fabricating a metal oxide semiconductor (MOS) transistor of an embedded memory, the method comprising:
providing a semiconductor wafer with both a memory array area and a periphery circuit region defined on the surface of a silicon substrate of the semiconductor wafer;
forming a first dielectric layer and an undoped polysilicon layer, respectively, on the surface of the semiconductor wafer;
performing an etching process to completely remove the undoped polysilicon layer and the first dielectric layer above the memory array area;
forming a second dielectric layer, a doped polysilicon layer, a silicide layer, a protection layer and a first photoresist layer, respectively, on the surface of the semiconductor wafer;
performing a first photolithographic process to define a plurality of gate patterns in the first photoresist layer above the memory array area;
using the gate patterns in the first photoresist layer as a hard mask to etch through the protection layer, the silicide layer, and the doped polysilicon layer down to the surface of the second dielectric layer;
performing a first ion implantation process to form a lightly doped drain (LDD) for each MOS transistor in the memory array area;
removing the first photoresist layer and the second dielectric layer above the periphery circuit region;
forming a second photoresist layer on the surface of the semiconductor wafer;
performing a second photolithographic process to define a plurality of gate patterns in the second photoresist layer above the periphery circuit region;
using the gate patterns in the second photoresist layer as a hard mask to etch through the undoped polysilicon layer down to the surface of the first dielectric layer above the periphery circuit region, to form gates for each MOS transistor in the periphery circuit region;
performing a second ion implantation process to form a lightly doped drain (LDD) for each MOS transistor in the periphery circuit region;
removing the second photoresist layer;
forming a silicon nitride layer on the surface of the semiconductor wafer and covering the surface of each gate;
removing portions of the silicon nitride layer in the periphery circuit region to form a spacer adjacent to each gate in the periphery circuit region; and
performing a third ion implantation process to form a source and a drain for each MOS transistor in the periphery circuit region, and simultaneously implanting the undoped polysilicon layer of each gate of each MOS transistor in the periphery circuit region.

2. The method of claim 1 wherein the first dielectric layer and the second dielectric layer are composed of silicon dioxide (SiO₂) with depths of 25˜45 angstroms (Å) and 70˜90 angstroms (Å), respectively, and serve as the gate oxide layer for each MOS transistor in the periphery circuit region and in the memory array area.

3. The method of claim 1 wherein the depths of the undoped polysilicon layer and the doped polysilicon layer are between 2000˜2500 angstroms (Å) and 600˜1000 angstroms (Å), respectively.

4. The method of claim 1 wherein the protection layer is composed of silicon nitride and a first silicon-oxy-nitride (SiOₓN_{y}) layer, serving as an anti-reflection coating (ARC) layer, is positioned between the protection layer and the silicide layer.

5. The method of claim 1 wherein a second silicon-oxy-nitride (SiOₓN_{y}) layer, serving as an anti-reflection coating (ARC) layer, is formed on the surface of the semiconductor wafer prior to the formation of the second photoresist layer.

6. The method of claim 5 wherein the second silicon-oxy-nitride (SiOₓN_{y}) layer, formed below the second photoresist layer, is removed after the removal of the second photoresist layer.

7. The method of claim i wherein after the formation of the source and drain of each MOS transistor in the periphery circuit region, the method also comprises:
forming a metal layer on the surface of the semiconductor wafer, as well covering the surfaces of the sources, drains, and the gates in the periphery circuit region;
performing a first rapid thermal process (RTP);
performing a wet etching process to remove the portions of the metal layer that do not react with the surface of the semiconductor wafer; and
performing a second rapid thermal process (RTP).

8. The method of claim 7 wherein the metal layer is composed of cobalt (Co), titanium (Ti), nickel (Ni), or molybdenum (Mo).

9. The method of claim 7 wherein the first rapid thermal process is performed at a temperature between 400° C. and 600° C. for a duration of 10 to 50 seconds, and the second rapid thermal process is performed at a temperature between 600° C. and 800° C. for a duration of 10 to 50 seconds.

10. A method for fabricating a metal oxide semiconductor (MOS) transistor of an embedded memory, the method comprising:
providing a semiconductor wafer with both a memory array area and a periphery circuit region defined on the surface of a silicon substrate of the semiconductor wafer, the memory array area comprising at least one cell-well, and the periphery circuit region comprising at least one N-well and at least one P-well;
forming a first dielectric layer and an undoped polysilicon layer, respectively, on the surface of the semiconductor wafer;
performing an etching process to completely remove both the undoped polysilicon layer and the first dielectric layer above the memory array area;
forming a second dielectric layer, a doped polysilicon layer, a silicide layer, a protection layer and a first photoresist layer, respectively, on the surface of the semiconductor wafer;
performing a first photolithographic process to define a plurality of gate patterns in the first photoresist layer above the cell-well of the memory array area;
using the gate patterns in the first photoresist layer as a hard mask to etch through the protection layer, the silicide layer, and the doped polysilicon layer down to the surface of the second dielectric layer;
removing the first photoresist layer
performing a first ion implantation process to form a lightly doped drain (LDD) for each MOS transistor in the memory array area;
removing the second dielectric layer above the periphery circuit region;
forming a second photoresist layer on the surface of the semiconductor wafer;
performing a second photolithographic process to define a plurality of gate patterns in the second photoresist layer above the N-well and the P-well of the periphery circuit region;
using the gate patterns in the second photoresist layer as a hard mask to etch through the undoped polysilicon layer down to the surface of the first dielectric layer above the periphery circuit region to form gates for each MOS transistor in the periphery circuit region;
removing the second photoresist layer;
performing a second ion implantation process to form a lightly doped drain (LDD) for each MOS transistor in the periphery circuit region;
forming a silicon nitride layer on the surface of the semiconductor and covering the surface of each gate;
etching the silicon nitride layer surrounding each gate above the P-well of the periphery circuit region to form a first spacer, and performing a third ion implantation process to form a source and drain of a NMOS in the P-well; and
etching the silicon nitride layer surrounding each gate above the N-well of the periphery circuit region to form a second spacer, and performing a fourth ion implantation process to form a source and drain of a PMOS in the N-well.

11. The method of claim 10 wherein the first dielectric layer and the second dielectric layer are composed of silicon dioxide (SiO₂) with depths of 25˜45 angstroms (Å) and 70˜90 angstroms (Å), respectively, and serve as the gate oxide layer for each MOS transistor in the periphery circuit region and in the memory array area.

12. The method of claim 10 wherein the depths of the undoped polysilicon layer and the doped polysilicon layer are between 2000˜2500 angstroms (Å) and 600˜1000 angstroms (Å), respectively.

13. The method of claim 10 wherein the protection layer is composed of silicon nitride and a first silicon-oxy-nitride (SiOₓN_{y}) layer, serving as an anti-reflection coating (ARC) layer, is positioned between the protection layer and the silicide layer.

14. The method of claim 10 wherein a second silicon-oxy-nitride (SiOₓN_{y}) layer, serving as an anti-reflection coating (ARC) layer, is formed on the surface of the semiconductor layer prior to the formation of the second photoresist layer on the surface of the semiconductor layer.

15. The method of claim 14 wherein the second silicon-oxy-nitride (SiOₓN_{y}) layer formed under the second photoresist layer must be removed after removing the second photoresist layer.

16. The method of claim 10 wherein the third and fourth ion implantation processes implant the undoped polysilicon layer of each gate above the P-well and the N-well, respectively.

17. The method of claim 10 wherein after the formation of the source and drain of each MOS transistor in the periphery circuit region, the method also comprises:
forming a metal layer on the surface of the semiconductor wafer as well as covering the surfaces of the sources, drains, and the gates in the periphery circuit region;
performing a first rapid thermal process (RTP);
performing a wet etching process to remove the portions of the metal layer that do not react with the surface of the semiconductor wafer; and
performing a second rapid thermal process (RTP).

18. The method of claim 17 wherein the metal layer is composed of cobalt (Co), titanium (Ti), nickel (Ni), or molybdenum (Mo).

19. The method of claim 17 wherein the first rapid thermal process is performed at a temperature between 400° C. and 600° C. for a duration of 10 to 50 seconds, and the second rapid thermal process is performed at a temperature between 600° C. and 800° C. for a duration of 10 to 50 seconds.
